(19) United States
(12) Patent Application Publication
(10) Pub. No.: US 2015/0115846 A1
(43) Pub. Date: Apr. 30, 2015

(54) PIEZOELECTRIC COOLING CONTROL APPARATUS AND METHOD

(71) Applicant: Electronics and Telecommunications Research Institute, Daejeon (KR)

(72) Inventors: Jongwoo CHOI, Daejeon (KR); Hyunchul KANG, Daejeon (KR); Hyunjoo KANG, Daejeon (KR); Seonghee PARK, Daejeon (KR); Jungsik SUNG, Daejeon (KR); Insu KIM, Daejeon (KR); Taegyu KANG, Daejeon (KR)

(21) Appl. No.: 14/522,370

(22) Filed: Oct. 23, 2014

(30) Foreign Application Priority Data
Oct. 25, 2013 (KR) 10-2013-0127641

(51) Int. Cl. H01L 41/04; H02P 29/00

(52) U.S. Cl. CPC H01L 41/042; H02P 29/0088
USPC 318/114

(57) ABSTRACT

The present invention relates to a piezoelectric cooling control apparatus and method, which set pulse parameters based on the temperature of the heating unit of a cooling target device, and thus control piezoelectric cooling. The piezoelectric cooling control apparatus includes a temperature sensing unit for sensing temperature of a heating unit of a cooling target device. A determination unit determines whether to activate piezoelectric cooling, based on the sensed temperature of the heating unit and a temperature setting range. A setting unit is configured to, if it is determined by the determination unit to activate piezoelectric cooling, set pulse parameters based on the temperature setting range and the temperature of the heating unit. A pulse control unit generates a PWM waveform based on the set pulse parameters and outputs the PWM waveform. A piezoelectric cooling unit performs piezoelectric cooling based on the PWM waveform.

### CROSS REFERENCE TO RELATED APPLICATION

This application claims the benefit of Korean Patent Application No. 10-2013-0127641, filed on Oct. 25, 2013, which is hereby incorporated by reference in its entirety into this application.

### BACKGROUND OF THE INVENTION

1. Technical Field

The present invention relates generally to a piezoelectric cooling control apparatus and method and, more particularly, to a piezoelectric cooling control apparatus and method, which control the activation of piezoelectric cooling.

2. Description of the Related Art

A piezoelectric phenomenon is a phenomenon in which conversion between electrical energy and mechanical energy appears. A direct piezoelectric effect denotes the effect of causing polarization when a mechanical stress is applied to a piezoelectric material, and refers to the effect of converting mechanical energy into electrical energy. An inverse piezoelectric effect denotes the effect of causing a piezoelectric material to be deformed when electricity is applied to the piezoelectric material, and refers to the effect of converting electrical energy into mechanical energy.

A piezoelectric phenomenon is applied to various fields and is chiefly used in areas related to vibrations. Such a piezoelectric phenomenon is utilized in products for controlling mechanical vibrations, such as a speaker, a microphone, a telephone, an ultrasonic washer, an ultrasonic accelerator, an acceleration sensor, a knocking sensor, and a vibration detector, or in power generators for converting mechanical operations into electrical energy.

Recently, cooling technology that uses a piezoelectric phenomenon to replace a cooling fan-type cooling technology has been developed. A cooling fan is disadvantageous in that it generates a lot of noise and has short lifespan, but a piezoelectric material used for cooling technology using the piezoelectric phenomenon is advantageous in that the lifespan thereof is long, and noise can be prevented if the piezoelectric material is controlled such that it vibrates at frequencies other than audible frequency.

The piezoelectric material expands or contracts when a voltage is applied thereto. If the polarity of a voltage is reversely applied, the piezoelectric material reversely contracts and expands. Therefore, if an Alternating Current (AC) voltage is applied, the piezoelectric material repeatedly extracts and contracts.

In this way, conventional cooling technology using a piezoelectric phenomenon causes vibrations in the piezoelectric material via the repetition of expansion and contraction of a piezoelectric material depending on the application of an AC voltage, and then may be utilized for producing an air flow and cooling the air.

However, the conventional piezoelectric cooling technology is a scheme for applying an AC voltage and controlling voltage/frequency. There is a problem in that, in order to utilize a piezoelectric cooler in an area exploiting Direct Current (DC) power or in a system containing a microcontroller, a separate circuit configuration is required to apply an AC voltage.

Korean Patent No. 10-0606736 (entitled “Cooling apparatus using piezoelectric fan”) and Korean Patent No. 10-1004161 (entitled “Piezoelectric fan, method of cooling microelectronic device using the same, and system including the same”) disclose the conventional cooling technology using a piezoelectric phenomenon.

### SUMMARY OF THE INVENTION

Accordingly, the present invention has been made keeping in mind the above problems occurring in the prior art, and an object of the present invention is to provide a piezoelectric cooling control apparatus and method, which set pulse parameters based on the temperature of the heating unit of a cooling target device and then control piezoelectric cooling. That is, the present invention is intended to sense the temperature of the heating unit of a cooling target device using a sensor or a thermocouple, thus controlling piezoelectric cooling via Pulse Width Modulation (PWM) when the temperature of the heating unit increases.

Another object of the present invention is to provide a piezoelectric cooling control apparatus and method, which actively control a cooling process depending on the temperature of a heating unit and control piezoelectric cooling without requiring a separate AC circuit. In particular, the present invention is intended to control piezoelectric cooling depending on the temperature in a system provided with a microcontroller.

In accordance with an aspect of the present invention to accomplish the above objects, there is provided a piezoelectric cooling control apparatus, including a temperature sensing unit for sensing temperature of a heating unit of a cooling target device; a determination unit for determining whether to activate piezoelectric cooling, based on the temperature of the heating unit sensed by the temperature sensing unit and a temperature setting range; a setting unit for, if it is determined by the determination unit to activate piezoelectric cooling, setting pulse parameters based on the temperature setting range and the temperature of the heating unit; a pulse control unit for generating a Pulse Width Modulation (PWM) waveform based on the set pulse parameters and outputting the PWM waveform; and a piezoelectric cooling unit for performing piezoelectric cooling based on the output PWM waveform.

The temperature sensing unit may sense the temperature of the heating unit either at preset periods or in response to occurrence of a preset event.

The determination unit may be configured to, if the heating unit is greater than a maximum value of the temperature setting range, determine to activate piezoelectric cooling.

The determination unit may be configured to, if the temperature of the heating unit is less than or equal to a minimum value of the temperature setting range during activation of piezoelectric cooling, determine to stop activation of the piezoelectric cooling.

The setting unit may set pulse parameters including a PWM period and a duty ratio.

The piezoelectric cooling control apparatus may further include a storage unit for storing the temperature setting range, with the temperature setting range divided into a plurality of setting stages, and storing the temperature setting range so that the pulse parameters are associated with respective setting stages, the setting unit is configured to, if it is determined by the determination unit to activate piezoelectric cooling, detect pulse parameters associated with a setting stage including the temperature of the heating unit from the storage unit, and set detected pulse parameters to pulse parameters required to activate piezoelectric cooling.

The piezoelectric cooling control apparatus may further include a storage unit for storing cooler characteristics including a period, a duty ratio, and polarity, wherein the setting unit is configured to, if it is determined by the determination unit to activate piezoelectric cooling, detect the cooler characteristics from the storage unit, and set the period, the duty ratio, and the polarity included in the detected cooler characteristics to pulse parameters.

The piezoelectric cooling control apparatus may further include a PWM driving unit for amplifying the PWM waveform output from the pulse control unit and outputting the amplified PWM waveform to the piezoelectric cooling unit.

In accordance with another aspect of the present invention to accomplish the above objects, there is provided a piezoelectric cooling control method, including sensing, by a temperature sensing unit, temperature of a heating unit of a cooling target device; determining, by a determination unit, whether to activate piezoelectric cooling, based on the sensed temperature of the heating unit and a temperature setting range; setting, by a setting unit, pulse parameters based on the temperature setting range and the temperature of the heating unit if it is determined to activate piezoelectric cooling; generating, by a pulse control unit, a Pulse Width Modulation (PWM) waveform based on the set pulse parameters and outputting the PWM waveform; and performing, by a piezoelectric cooling unit, piezoelectric cooling based on the output PWM waveform.

The sensing the temperature of the heating unit may be configured such that the temperature of the heating unit is sensed by the temperature sensing unit either at preset periods or in response to occurrence of a preset event.

The determining may be configured such that, if the heating unit is greater than a maximum value of the temperature setting range, it is determined by the determination unit to activate piezoelectric cooling.

The setting may be configured such that pulse parameters including a PWM period and a duty ratio are set by the setting unit.

The setting may include detecting, by the setting unit, a setting stage including the temperature of the heating unit from a plurality of pre-stored setting stages; and detecting, by the setting unit, pulse parameters associated with the detected setting stage, and setting, by the setting unit, the detected pulse parameters to pulse parameters required to activate piezoelectric cooling.

The setting may include detecting, by the setting unit, pre-stored cooler characteristics if it is determined to activate piezoelectric cooling; and setting, by the setting unit, a period, a duty ratio, and polarity included in the detected cooler characteristics to the pulse parameters.

The determining may be configured such that, if the temperature of the heating unit is less than or equal to a minimum value of the temperature setting range during activation of piezoelectric cooling, it is determined by the determination unit to stop activation of the piezoelectric cooling.

The piezoelectric cooling control method may further include discontinuing, by the pulse control unit, generation and output of the PWM waveform if it is determined to stop activation of piezoelectric cooling.

The piezoelectric cooling control method may further include amplifying, by a PWM driving unit, the output PWM waveform and outputting, by the PWM driving unit, the amplified PWM waveform to the piezoelectric cooling unit.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing a piezoelectric cooling control apparatus according to an embodiment of the present invention;

FIG. 2 is a block diagram showing the configuration of a piezoelectric cooling control apparatus according to an embodiment of the present invention;

FIGS. 3 to 5 are diagrams showing the configuration of the piezoelectric cooling unit of FIG. 2;

FIG. 6 is a flowchart showing a piezoelectric cooling control method according to an embodiment of the present invention; and

FIGS. 7 and 8 are flowcharts showing the pulse parameter setting step of FIG. 6.

### DESCRIPTION OF THE PREFERRED EMBODIMENTS

Embodiments of the present invention are described with reference to the accompanying drawings in order to describe the present invention in detail so that those having ordinary knowledge in the technical field to which the present invention pertains can easily practice the present invention. It should be noted that the same reference numerals are used to designate the same or similar elements throughout the drawings. In the following description of the present invention, detailed descriptions of known functions and configurations which are deemed to make the gist of the present invention obscure will be omitted.

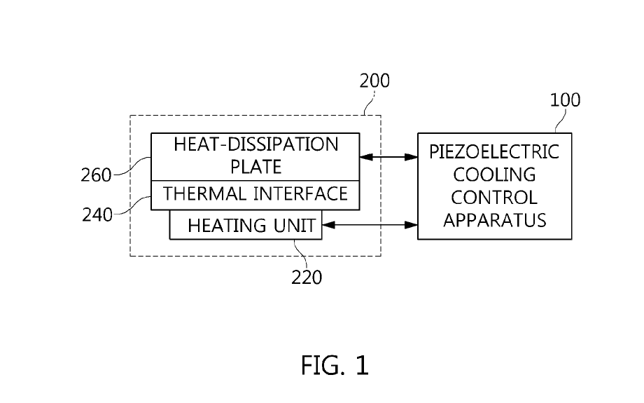

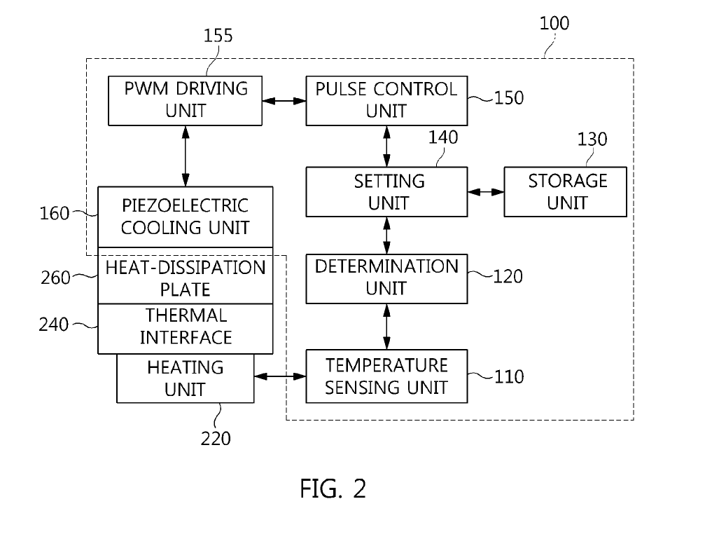

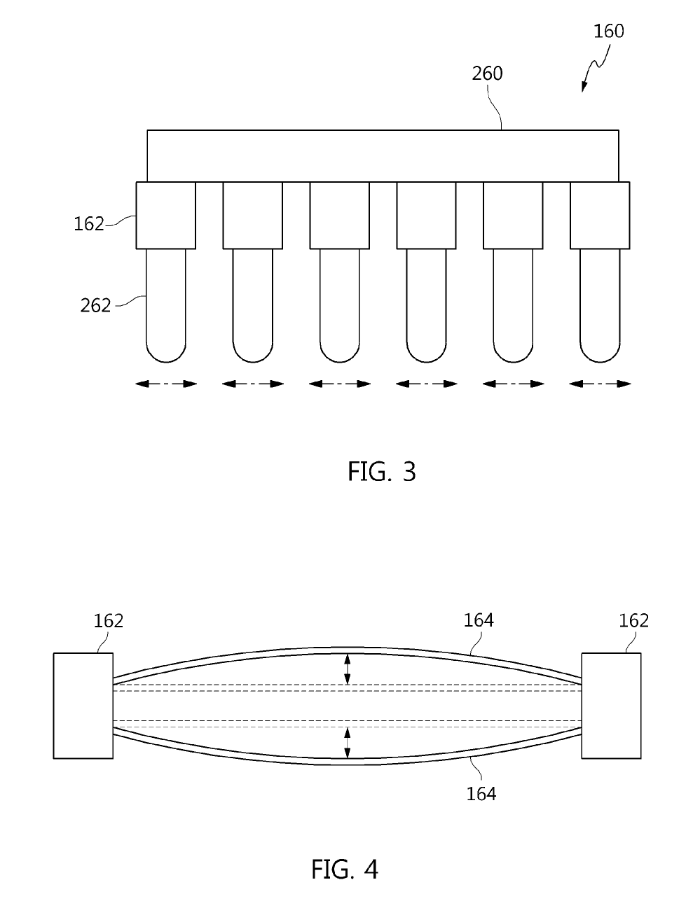

Hereinafter, a piezoelectric cooling control apparatus according to an embodiment of the present invention will be described in detail with reference to the attached drawings. FIG. 1 is a diagram showing a piezoelectric cooling control apparatus according to an embodiment of the present invention, and FIG. 2 is a block diagram showing the configuration of a piezoelectric cooling control apparatus according to an embodiment of the present invention. FIGS. 3 to 5 are diagrams showing the configuration of the piezoelectric cooling unit of FIG. 2.

As shown in FIG. 1, a piezoelectric cooling control apparatus 100 sets pulse parameters depending on the temperature of a cooling target device 200. The piezoelectric cooling control apparatus 100 cools the cooling target device 200 by generating a refrigerant flow in a piezoelectric manner. In this case, the cooling target device 200 includes a heating unit 220 which is a heat generation region and which transfers heat to an external system and decreases the temperature thereof, a thermal interface 240 which is a material used to prevent the occurrence of a thermal bottleneck in a contact region, and a heat-dissipation plate 260 which dissipates heat to an external refrigerant.

As shown in FIG. 2, the piezoelectric cooling control apparatus 100 includes a temperature sensing unit 110, a determination unit 120, a storage unit 130, a setting unit 140, a pulse control unit 150, a Pulse Width Modulation (PWM) driving unit 155, and a piezoelectric cooling unit 160.

The temperature sensing unit 110 senses the temperature of the heating unit of the cooling target device 200. The temperature sensing unit 110 senses the temperature of the heating unit either at preset periods or in response to the occurrence of a preset event. The temperature sensing unit 110 is implemented using a sensor or a thermocouple and is installed closer to the heating unit 220 of the cooling target device 200.

The determination unit 120 determines whether to activate piezoelectric cooling, based on the temperature of the heating unit sensed by the temperature sensing unit 110 and a temperature setting range. That is, the determination unit 120 determines not to drive the piezoelectric cooling unit 160 if the temperature of the heating unit is greater than a lower critical temperature (that is, the minimum value of the temperature setting range) and is less than an upper critical temperature (that is, the maximum value of the temperature setting range). Further, if the temperature of the heating unit is greater than the upper critical temperature, the determination unit 120 determines to activate piezoelectric cooling. The determination unit 120 determines to stop the activation of piezoelectric cooling if the temperature of the heating unit is less than or equal to the lower critical temperature during the activation of piezoelectric cooling.

The storage unit 130 stores the temperature setting range, with the temperature setting range divided into a plurality of setting stages. The storage unit 130 stores the temperature setting range so that pulse parameters are associated with respective setting stages. In this case, the storage unit 130 stores the temperature setting range so that pulse parameters including a period and a duty ratio are associated with the setting stages. The storage unit 130 stores the temperature setting range so that pulse parameters for maximizing the vibration of the piezoelectric cooling unit 160 are associated with a setting stage corresponding to the maximum value of the temperature setting range. The storage unit 130 stores the temperature setting range so that, as the temperature of the setting stages decreases, pulse parameters for reducing vibration are associated with the corresponding setting stages. Accordingly, the storage unit 130 stores the temperature setting range so that pulse parameters for minimizing vibration are associated with a setting stage corresponding to the minimum value of the temperature setting range.

The storage unit 130 stores the characteristics of a cooler forming the piezoelectric cooling unit 160. That is, in the case of the cooler forming the piezoelectric cooling unit 160, if polarities are reversed, expansion and contraction occur reversely. Therefore, the storage unit 130 stores cooler characteristics including the period, duty ratio, and polarity of the piezoelectric cooling unit 160. Here, the storage unit 130 may selectively store cooler characteristics other than polarity because piezoelectric coolers have various types and shapes.

The setting unit 140 is configured to, if it is determined by the determination unit 120 to activate piezoelectric cooling, set pulse parameters including a PWM period required to set an increase or a decrease in vibration, and a duty ratio required to set the expansion (or contraction) degree of piezoelectric elements (piezoelectric material) 162.

The setting unit 140 is configured to, if it is determined by the determination unit 120 to activate piezoelectric cooling, set the pulse parameters based on the temperature setting range and the temperature of the heating unit. That is, the setting unit 140 detects a plurality of setting stages from the storage unit 130. The setting unit 140 compares the temperature of the heating unit received from the temperature sensing unit 110 with the plurality of setting stages, and detects a setting stage including the temperature of the heating unit. The setting unit 140 detects pulse parameters associated with the detected setting stage from the storage unit 130. By means of this, the setting unit 140 sets the pulse parameters so that the vibration of the piezoelectric cooling unit 160 varies according to variation in the temperature of the heating unit.

The setting unit 140 is configured to, if it is determined by the determination unit 120 to activate piezoelectric cooling, detect cooler characteristics from the storage unit 130, and set the cooler characteristics to pulse parameters. That is, the setting unit 140 sets fixed pulse parameters depending on the period, duty ratio, and polarity included in the cooler characteristics. By means of this, the setting unit 140 sets pulse parameters so that the piezoelectric cooling unit 160 is driven at the same vibration until the determination unit 120 determines to stop the activation of piezoelectric cooling.

The pulse control unit 150 is configured to, if it is determined by the determination unit 120 to activate piezoelectric cooling, generate a Pulse Width Modulation (PWM) waveform based on the pulse parameters set by the setting unit 140. That is, the pulse control unit 150 generates a PWM waveform according to the period and duty ratio of the pulse parameters and transmits the PWM waveform to the PWM driving unit 155. In this case, if it is determined by the determination unit 120 to stop the activation of piezoelectric cooling, the pulse control unit 150 discontinues the generation and transmission of the PWM waveform.

The PWM driving unit 155 amplifies the PWM waveform received from the pulse control unit 150 to a predetermined level, and transmits the amplified PWM waveform to the piezoelectric cooling unit 160. That is, the PWM driving unit 155 amplifies the PWM waveform generated by the pulse control unit 150 depending on the voltage and current characteristics of the piezoelectric cooling unit 160 and transmits the amplified PWM waveform.

The piezoelectric cooling unit 160 is driven in response to the PWM waveform received from the PWM driving unit 155 to perform cooling control. That is, the heating unit 220 is cooled using the flow of refrigerant occurring due to the repetition of the expansion (or contraction) and stoppage of the piezoelectric elements 162 forming the piezoelectric cooling unit 160. In this case, in the piezoelectric cooling unit 160, if the period is shorter, vibration frequency is higher, whereas if the period is longer, the vibration frequency is lower. In the piezoelectric cooling unit 160, as the duty ratio is higher, the degree of expansion (or contraction) of the piezoelectric cooling unit 160 is higher, whereas if the duty ratio is lower, the degree of expansion (or contraction) is lower. If the polarities of the piezoelectric cooling unit 160 are reversed, expansion and contraction occur reversely.

The piezoelectric cooling unit 160 may be implemented in various forms. Below, the configuration of the piezoelectric cooling unit 160 will be described as an example with reference to FIGS. 3 to 5.

As shown in FIG. 3, the piezoelectric cooling unit 160 is configured such that piezoelectric elements 162 are installed on a heat dissipation plate 260. That is, the piezoelectric elements 162 are attached to respective heat-dissipation plate pins 262. The piezoelectric elements 162 repeat expansion (or contraction) and stoppage depending on the PWM waveform. Accordingly, a cooling effect occurs due to friction between the heat dissipation plate 260 and external refrigerant.

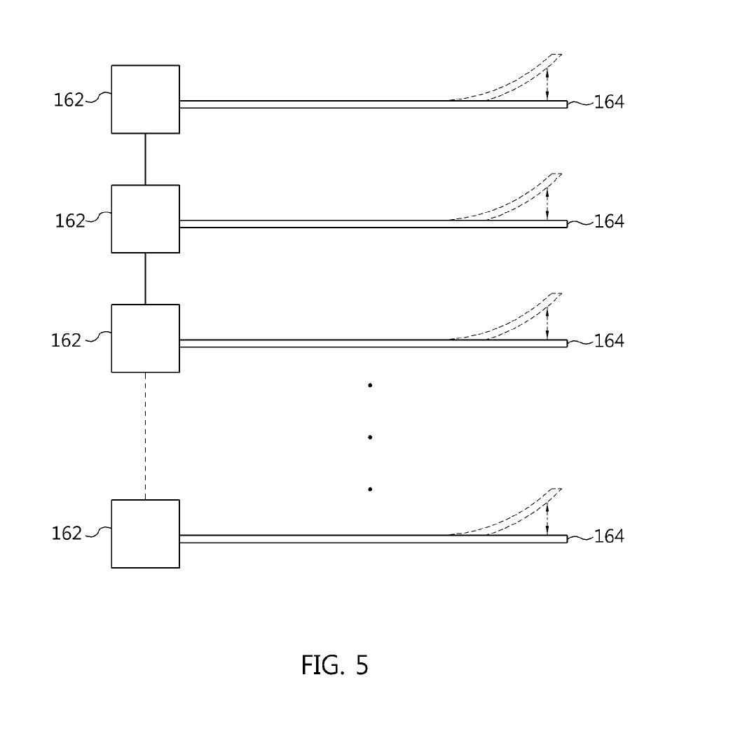

As shown in FIG. 4, the piezoelectric cooling unit 160 is configured such that two piezoelectric plates 164 are arranged in parallel and the piezoelectric elements 162 are installed at both ends of each piezoelectric plate 164. When a PWM waveform is applied to the piezoelectric elements 162, the piezoelectric plates 164 vibrate vertically due to the expansion (or contraction) and stoppage of the piezoelectric elements 162. Accordingly, the piezoelectric cooling unit 160 functions as a pump for floating the refrigerant and supplies the refrigerant to the surroundings, thus producing a cooling effect.

As shown in FIG. 5, the piezoelectric cooling unit 160 is configured such that the piezoelectric elements 162 are installed at first ends of one or more piezoelectric plates 164. When a PWM waveform is applied to the piezoelectric elements 162, vibration is applied to the piezoelectric plates 164 due to the expansion (or contraction) and stoppage of the piezoelectric elements 162. Accordingly, the second ends of the piezoelectric plates 164 vibrate, thus causing the refrigerant to flow. The piezoelectric cooling unit 160 controls the flow direction of the refrigerant via the vibration of the piezoelectric plates 164, thus producing a cooling effect.

The piezoelectric cooling unit 160 may be installed on the heating unit 220 or the heat dissipation plate 260. In order to increase the cooling effect, the piezoelectric cooling unit 160 is preferably installed as close to the heat dissipation plate 260 as possible.

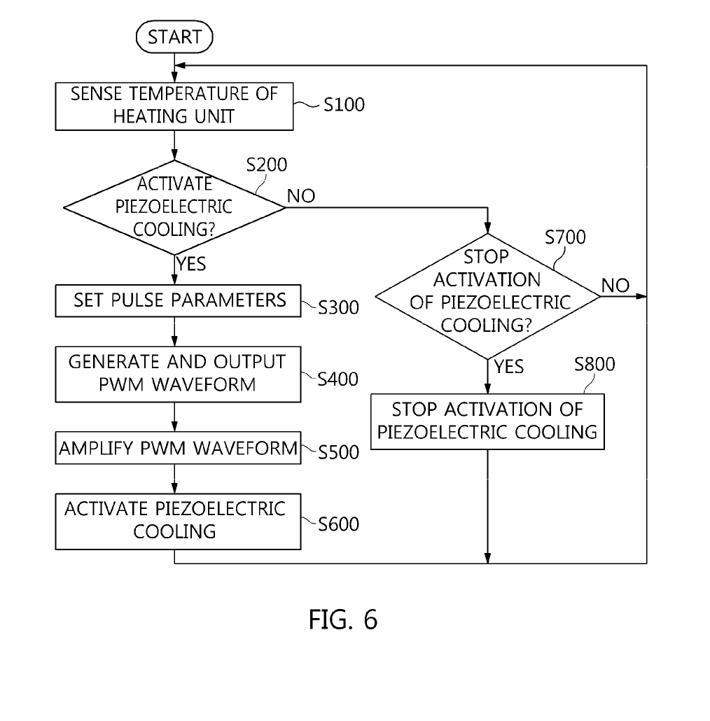

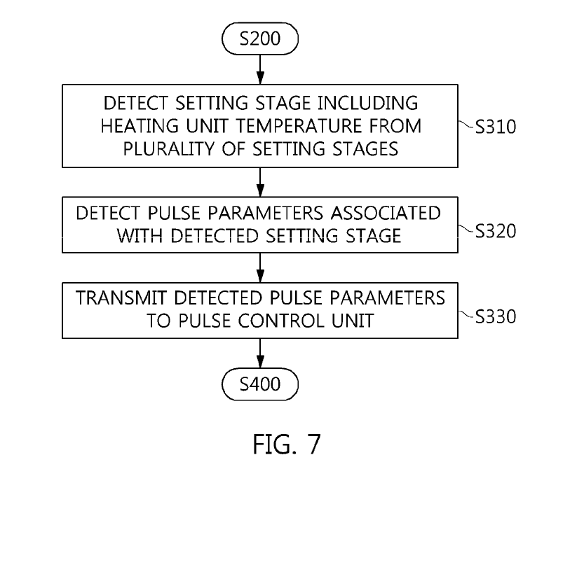

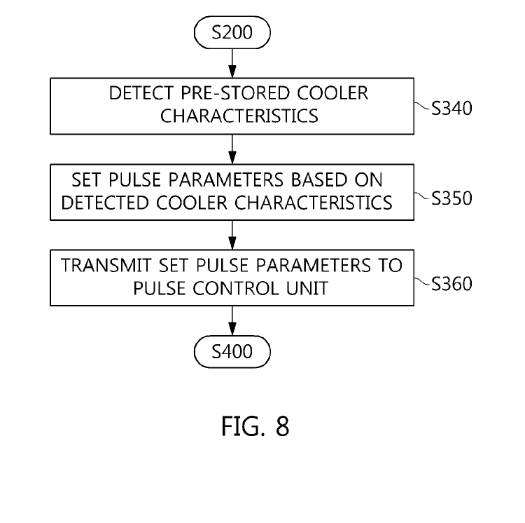

Hereinafter, a piezoelectric cooling control method according to an embodiment of the present invention will be described in detail with reference to the attached drawings. FIG. 6 is a flowchart showing a piezoelectric cooling control method according to an embodiment of the present invention, and FIGS. 7 and 8 are flowcharts showing the pulse parameter setting step of FIG. 6.

The temperature sensing unit 110 senses the temperature of the heating unit of the cooling target device 200 at step S100. That is, the temperature sensing unit 110 senses the temperature of the heating unit either at preset periods, or in response to the occurrence of a preset event. The temperature sensing unit 110 transmits the sensed heating unit temperature to the determination unit 120 and to the setting unit 140.

The determination unit 120 determines whether to activate piezoelectric cooling, based on the temperature of the heating unit and a temperature setting range. In this case, the determination unit 120 is configured to, if the temperature of the heating unit is greater than an upper critical temperature (that is, the maximum value of the temperature setting range), determine to activate piezoelectric cooling. If the temperature of the heating unit is greater than a lower critical temperature (that is, the minimum value of the temperature setting range) and is less than the upper critical temperature, the determination unit 120 determines not to drive the piezoelectric cooling unit 160. If it is determined by the determination unit 120 to activate piezoelectric cooling (Yes at step S200), the setting unit 140 sets pulse parameters required to activate piezoelectric cooling at step S300. In this case, the setting unit 140 sets pulse parameters including a PWM period required to set an increase or a decrease in the vibration of the piezoelectric elements 162, and a duty ratio required to set the degree of the expansion (or contraction) of the piezoelectric elements 162. Here, the pulse parameter setting step will be described in detail below with reference to FIGS. 7 and 8.

Referring to FIG. 7, the storage unit 130 stores the temperature setting range, with temperature setting range divided into a plurality of setting stages. The storage unit 130 stores the temperature setting range so that pulse parameters are associated with respective setting stages. In this case, the storage unit 130 stores the temperature setting range so that the pulse parameters including the period and the duty ratio are associated with the respective setting stages. The setting unit 140 detects a setting stage including the temperature of the heating unit from the plurality of setting stages stored in the storage unit 130 at step S310.

The setting unit 140 detects pulse parameters associated with the detected setting stage from the storage unit 130 at step S320, and transmits the detected pulse parameters to the pulse control unit 150 at step S330. By means of this, the setting unit 140 adjusts the vibration of the piezoelectric elements 162 depending on the temperature of the heating unit, and sets pulse parameters so that the piezoelectric cooling unit 160 is driven at different vibrations.

Referring to FIG. 8, the storage unit 130 stores the characteristics of a cooler forming the piezoelectric cooling unit 160. That is, the storage unit 130 stores cooler characteristics including the period, duty ratio, and polarity of the piezoelectric cooling unit 160. If it is determined by the determination unit 140 to activate piezoelectric cooling, the setting unit 140 detects the cooler characteristics from the storage unit 130 at step S340.

The setting unit 140 sets pulse parameters based on the detected cooler characteristics at step S350. That is, the setting unit 140 sets fixed pulse parameters based on the period, duty ratio, and polarity included in the detected cooler characteristics. By means of this, the setting unit 140 sets pulse parameters so that the piezoelectric cooling unit 160 is driven at the same vibration until the determination unit 120 determines to stop the activation of piezoelectric cooling.

If it is determined by the determination unit 120 to activate piezoelectric cooling, the pulse control unit 150 generates a PWM waveform based on the pulse parameters set by the setting unit 140, and transmits the PWM waveform to the PWM driving unit 155 at step S400. That is, the pulse control unit 150 generates the PWM waveform depending on the period and duty ratio of the pulse parameters, and transmits the PWM waveform to the PWM driving unit 155.

The PWM driving unit 155 amplifies the PWM waveform received from the pulse control unit 150 to a predetermined level, and transmits the amplified PWM waveform to the piezoelectric cooling unit 160 at step S500. That is, the PWM driving unit 155 amplifies the PWM waveform generated by the pulse control unit 150 depending on the voltage and current characteristics of the piezoelectric cooling unit 160, and transmits the amplified PWM waveform.

Accordingly, the piezoelectric cooling unit 160 is driven in response to the PWM waveform received from the PWM driving unit 155 to activate piezoelectric cooling at step S600. That is, the piezoelectric cooling unit 160 applies the received PWM waveform to the piezoelectric elements 162. Accordingly, the piezoelectric elements 162 cool the heating unit 220 using the flow of refrigerant occurring due to the repetition of expansion (or contraction) and stoppage.

Meanwhile, the determination unit 120 determines whether to stop the activation of piezoelectric cooling, based on the heating unit temperature, received from the temperature sensing unit 110, and the temperature setting range during the activation of piezoelectric cooling. In this case, the determination unit 120 determines to stop the activation of piezoelectric cooling if the heating unit temperature is less than or equal to the lower critical temperature during the activation of piezoelectric cooling. If it is determined by the determination unit 120 to stop the activation of piezoelectric cooling (Yes at step S700), the pulse control unit 150 stops piezoelectric cooling at step S800. That is, the pulse control unit 150 discontinues the generation and transmission of the PWM waveform, thus stopping the activation of piezoelectric cooling.

As described above, the piezoelectric cooling control apparatus and method are advantageous in that piezoelectric cooling is controlled by setting pulse parameters based on the temperature of the heating unit of a cooling target device, so that piezoelectric cooling is activated depending on the temperature, thus improving power efficiency, and activating and controlling piezoelectric cooling without requiring a separate AC circuit.

Further, the piezoelectric cooling control apparatus and method are advantageous in that piezoelectric cooling is controlled by setting pulse parameters based on the temperature of the heating unit of a cooling target device, thus providing an efficient active heat-dissipation function.

Although the preferred embodiments of the present invention have been disclosed for illustrative purposes, the present invention may be modified in various forms, and those skilled in the art will appreciate that various modifications and changes are possible, without departing from the scope and spirit of the invention as disclosed in the accompanying claims.

What is claimed is:

1. A piezoelectric cooling control apparatus, comprising:
a temperature sensing unit for sensing temperature of a heating unit of a cooling target device;
a determination unit for determining whether to activate piezoelectric cooling, based on the temperature of the heating unit sensed by the temperature sensing unit and a temperature setting range;
a setting unit for, if it is determined by the determination unit to activate piezoelectric cooling, setting pulse parameters based on the temperature setting range and the temperature of the heating unit;
a pulse control unit for generating a Pulse Width Modulation (PWM) waveform based on the set pulse parameters and outputting the PWM waveform; and
a piezoelectric cooling unit for performing piezoelectric cooling based on the output PWM waveform.

2. The piezoelectric cooling control apparatus of claim 1, wherein the temperature sensing unit senses the temperature of the heating unit either at preset periods or in response to occurrence of a preset event.

3. The piezoelectric cooling control apparatus of claim 1, wherein the determination unit is configured to, if the heating unit is greater than a maximum value of the temperature setting range, determine to activate piezoelectric cooling.

4. The piezoelectric cooling control apparatus of claim 1, wherein the determination unit is configured to, if the temperature of the heating unit is less than or equal to a minimum value of the temperature setting range during activation of piezoelectric cooling, determine to stop activation of the piezoelectric cooling.

5. The piezoelectric cooling control apparatus of claim 1, wherein the setting unit sets pulse parameters including a PWM period and a duty ratio.

6. The piezoelectric cooling control apparatus of claim 1, further comprising a storage unit for storing the temperature setting range, with the temperature setting range divided into a plurality of setting stages, and storing the temperature setting range so that the pulse parameters are associated with respective setting stages,
wherein the setting unit is configured to, if it is determined by the determination unit to activate piezoelectric cooling, detect pulse parameters associated with a setting stage including the temperature of the heating unit from the storage unit, and set detected pulse parameters to pulse parameters required to activate piezoelectric cooling.

7. The piezoelectric cooling control apparatus of claim 1, further comprising a storage unit for storing cooler characteristics including a period, a duty ratio, and polarity,
wherein the setting unit is configured to, if it is determined by the determination unit to activate piezoelectric cooling, detect the cooler characteristics from the storage unit, and set the period, the duty ratio, and the polarity included in the detected cooler characteristics to pulse parameters.

8. The piezoelectric cooling control apparatus of claim 1, further comprising a PWM driving unit for amplifying the PWM waveform output from the pulse control unit and outputting the amplified PWM waveform to the piezoelectric cooling unit.

9. A piezoelectric cooling control method, comprising:
sensing, by a temperature sensing unit, temperature of a heating unit of a cooling target device;
determining, by a determination unit, whether to activate piezoelectric cooling, based on the sensed temperature of the heating unit and a temperature setting range;
setting, by a setting unit, pulse parameters based on the temperature setting range and the temperature of the heating unit if it is determined to activate piezoelectric cooling;
generating, by a pulse control unit, a Pulse Width Modulation (PWM) waveform based on the set pulse parameters and outputting the PWM waveform; and
performing, by a piezoelectric cooling unit, piezoelectric cooling based on the output PWM waveform.

10. The piezoelectric cooling control method of claim 9, wherein the sensing the temperature of the heating unit is configured such that the temperature of the heating unit is sensed by the temperature sensing unit either at preset periods or in response to occurrence of a preset event.

11. The piezoelectric cooling control method of claim 9, wherein the determining is configured such that, if the heating unit is greater than a maximum value of the temperature setting range, it is determined by the determination unit to activate piezoelectric cooling.

12. The piezoelectric cooling control method of claim 9, wherein the setting is configured such that pulse parameters including a PWM period and a duty ratio are set by the setting unit.

13. The piezoelectric cooling control method of claim 9, wherein the setting comprises:
detecting, by the setting unit, a setting stage including the temperature of the heating unit from a plurality of pre-stored setting stages; and
detecting, by the setting unit, pulse parameters associated with the detected setting stage, and setting, by the setting unit, the detected pulse parameters to pulse parameters required to activate piezoelectric cooling.

14. The piezoelectric cooling control method of claim 9, wherein the setting comprises:
detecting, by the setting unit, pre-stored cooler characteristics if it is determined to activate piezoelectric cooling; and
setting, by the setting unit, a period, a duty ratio, and polarity included in the detected cooler characteristics to the pulse parameters.

15. The piezoelectric cooling control method of claim 9, wherein the determining is configured such that, if the temperature of the heating unit is less than or equal to a minimum value of the temperature setting range during activation of piezoelectric cooling, it is determined by the determination unit to stop activation of the piezoelectric cooling.

16. The piezoelectric cooling control method of claim 15, further comprising discontinuing, by the pulse control unit, generation and output of the PWM waveform if it is determined to stop activation of piezoelectric cooling.

17. The piezoelectric cooling control method of claim 9, further comprising amplifying, by a PWM driving unit, the output PWM waveform and outputting, by the PWM driving unit, the amplified PWM waveform to the piezoelectric cooling unit.
